(19) United States
(12) Patent Application Publication
(10) Pub. No.: US 2026/0212900 A1
(43) Pub. Date: Jul. 23, 2026

(54) BIT CELL AND INTEGRATED CIRCUIT DEVICE INCLUDING THE SAME

(71) Applicant: SAMSUNG ELECTRONICS CO., LTD., SUWON-SI (KR)

(72) Inventors: Jiwon PARK, Suwon-si (KR); Kyowook LEE, Suwon-si (KR)

(73) Assignee: SAMSUNG ELECTRONICS CO., LTD., SUWON-SI (KR)

(21) Appl. No.: 19/328,870

(22) Filed: Sep. 15, 2025

(30) Foreign Application Priority Data
Jan. 22, 2025 (KR) 10-2025-0009824

(51) Int. Cl. G11C 5/06; G11C 11/419

(52) U.S. Cl. CPC G11C 5/063; G11C 11/419

(57) ABSTRACT

A bit cell including a read port and a write port, comprises a plurality of active regions spaced apart from each other in parallel in a first direction and extending in a second direction perpendicular to the first direction; and a plurality of gates spaced apart from each other in parallel in the second direction, extending in the first direction, and arranged in at least one of the plurality of active regions to each form a transistor. The read port includes a read pass transistor and a read pull-down transistor. The write port includes a first pass transistor, a second pass transistor, a first pull-down transistor, a second pull-down transistor, a first pull-up transistor, and a second pull-up transistor. The read pass transistor, the read pull-down transistor, the first pass transistor, and the first pull-down transistor share one active region.

### CROSS-REFERENCE TO RELATED APPLICATION

This application is based on and claims priority under 35 U.S.C. § 119 to Korean Patent Application No. 10-2025-0009824, filed on Jan. 22, 2025, in the Korean Intellectual Property Office, the disclosure of which is incorporated by reference herein in its entirety.

### BACKGROUND

The inventive concept relates to a bit cell and an integrated circuit device including the same, and more particularly, to a two-port static random-access memory (SRAM) cell and an integrated circuit device including the same.

Technology related to semiconductor devices is experiencing remarkable growth and continuous development worldwide due to the active demands of semiconductor users and the continuous efforts of semiconductor manufacturers. In addition, the semiconductor manufacturers are striving to make semiconductor devices even smaller, more integrated, and larger in size, while also spurring research and development to enable more stable and smooth operation and faster speeds. The efforts of these semiconductor manufacturers have led to advancements in fine process technology, ultra-small component technology, and circuit design technology, which have resulted in remarkable achievements in the technology of semiconductor memory cells, such as dynamic random-access memory (DRAM) and SRAM.

In the case of the two-port SRAM, high-speed read and write operations can be performed, compared to conventional single-port SRAM. However, in the case of the two-port SRAM, the area of the unit memory cell can increase as the number of transistors included in one unit memory cell increases, compared to the conventional single-port SRAM.

### SUMMARY

The inventive concept provides a bit cell with excellent operating characteristics and improved integration, and an integrated circuit device including the same.

The inventive concept is not limited to the mentioned above, and other inventive concepts not mentioned will be clearly understood by those skilled in the art from the following description.

According to an aspect of the inventive concept, there is provided a bit cell including a read port and a write port, comprises a plurality of active regions spaced apart from each other in parallel in a first direction and extending in a second direction perpendicular to the first direction, and a plurality of gates spaced apart from each other in parallel in the second direction, extending in the first direction, and arranged in at least one of the plurality of active regions to each form a transistor. The read port includes a read pass transistor and a read pull-down transistor, the write port includes a first pass transistor, a second pass transistor, a first pull-down transistor, a second pull-down transistor, a first pull-up transistor, and a second pull-up transistor, and the read pass transistor, the read pull-down transistor, the first pass transistor, and the first pull-down transistor share one active region.

According to another aspect of the inventive concept, there is provided a bit cell including a read port and a write port. The read port includes a read pass transistor and a read pull-down transistor, the write port includes a first pass transistor, a second pass transistor, a first pull-down transistor, a second pull-down transistor, a first pull-up transistor, and a second pull-up transistor, and the read pass transistor, the read pull-down transistor, the first pass transistor, and the first pull-down transistor share one active region.

According to another aspect of the inventive concept, there is provided an integrated circuit device including a bit cell including a read port and a write port, wherein the integrated circuit device includes a plurality of active regions including a first active region, a second active region, a third active region, and a fourth active region, which are spaced apart from each other in parallel in a first direction and extend in a second direction perpendicular to the first direction, and a plurality of gates including a first gate, a second gate, a third gate, and a fourth gate, which are spaced apart from each other in parallel in the second direction, extend in the first direction, and are arranged in at least one of the plurality of active regions to each form a transistor, wherein the read port includes a read pass transistor and a read pull-down transistor, the write port includes a first pass transistor, a second pass transistor, a first pull-down transistor, a second pull-down transistor, a first pull-up transistor, and a second pull-up transistor, and the read pass transistor, the read pull-down transistor, the first pass transistor, and the first pull-down transistor share one active region.

### BRIEF DESCRIPTION OF THE DRAWINGS

Embodiments will be more clearly understood from the following detailed description taken in conjunction with the accompanying drawings in which:

FIG. 1 is a block diagram of an integrated circuit device according to an embodiment;

FIG. 2 is a circuit diagram of a bit cell according to some embodiments;

FIGS. 3 to 6 are layout diagrams of the bit cell, according to some embodiments;

FIG. 7 is a cross-sectional view of an integrated circuit device according to some embodiments; and

FIGS. 8 to 12 are cross-sectional views of a portion of the integrated circuit device taken along line Y1-Y1′ in FIG. 6 to illustrate a method of manufacturing the integrated circuit device in accordance with a process sequence, according to an embodiment.

### DETAILED DESCRIPTION OF THE EMBODIMENTS

Hereinafter, embodiments are described in detail with reference to the attached drawings. The same reference numerals are used for identical components in the drawings, and duplicate descriptions thereof are omitted.

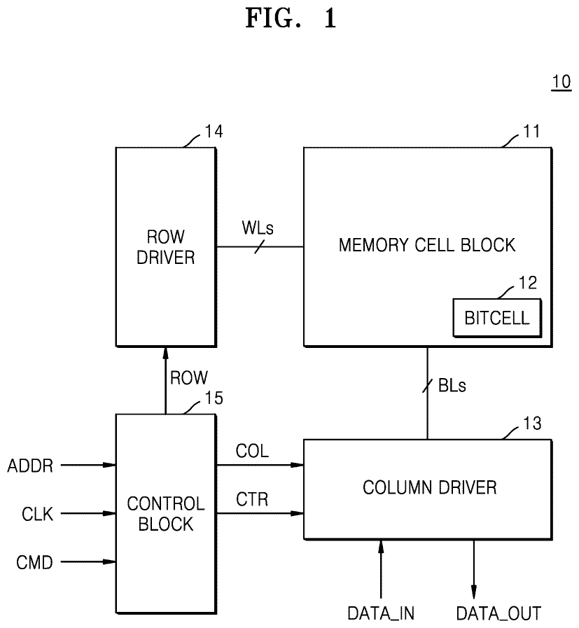

FIG. 1 is a block diagram of an integrated circuit device 10 according to an embodiment.

Referring to FIG. 1, the integrated circuit device 10 may receive a command CMD, an address ADDR, a clock CLK, and write data DATA_IN. For example, the integrated circuit device 10 may receive the command CMD (which may be referred to as a write command) instructing to write data, the address ADDR (which may be refers to as a write address), and the write data DATA_IN and may store the write data DATA_IN in a region of a memory cell block 11 corresponding to the address ADDR. In addition, the integrated circuit device 10 may receive the command CMD (which may be referred to as a read command) instructing to read data and the address ADDR (which may be refers to as a read address) and may output read data DATA_OUT stored in a region of the memory cell block 11 corresponding to the address ADDR to the outside.

The memory cell block 11 may include a plurality of bit cells 12. The plurality of bit cells 12 may be spaced apart from each other at regular intervals. The plurality of bit cells 12 may be arranged at intersections of word lines WLs and bit lines BLs. That is, each of the plurality of bit cells 12 may be connected to at least one of the word lines WLs and may be connected to at least one of the bit lines BLs.

Each of the plurality of bit cells 12 may include a memory cell. For example, each of the plurality of bit cells 12 may include static random-access memory (SRAM) or may include a volatile memory cell, such as dynamic random-access memory (DRAM). In particular, each of the plurality of bit cells 12 may include a two-port SRAM (TPSRAM) cell, where a write port is separated from a read port. In some embodiments, the plurality of bit cells 12 may include non-volatile memory cells, such as flash memory or resistive random-access memory (RRAM). Embodiments are described mainly with reference to the TPSRAM cell, but the inventive concept is not limited thereto.

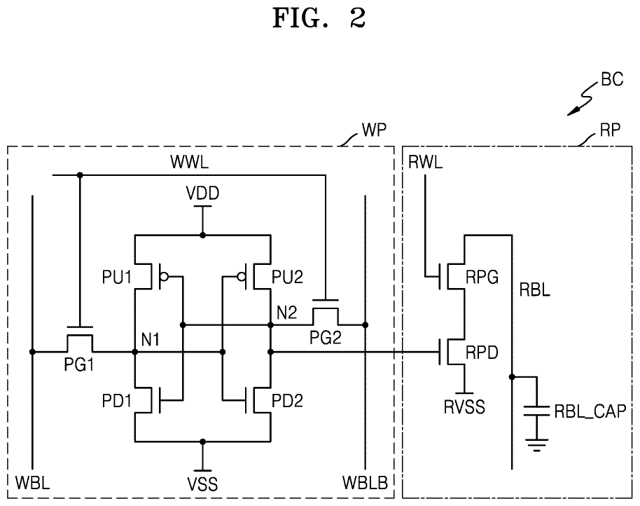

A column driver 13 may be connected to the memory cell block 11 through the bit lines BLs. The column driver 13 may select at least one of the bit lines BLs based on a column address COL. For example, the column driver 13 may select a first bit line (e.g., WBL of FIG. 2) and a second bit line (e.g., WBLB of FIG. 2), which is complementary to the first write bit line. The first bit line and the second bit line may be connected to any one of the plurality of bit cells 12. As the column driver 13 selects the first bit line and the second bit line, the plurality of bit cells 12 connected to the first write bit line or the second write bit line may be selected.

The column driver 13 may perform a read operation or a write operation based on a control signal CTR. The column driver 13 may detect a current and/or a voltage received through the bit lines BLs, thereby identifying values stored in a bit cell connected to an activated word line among the plurality of bit cells 12 and outputting the read data DATA_OUT based on the identified values. The column driver 13 may apply a current and/or a voltage to the bit lines BLs based on the write data DATA_IN and may write values to the bit cell connected to the activated word line among the plurality of bit cells 12. According to an embodiment, the column driver 13 may include a read circuit that performs the read operation and a write circuit that performs the write operation. Although not shown, the column driver 13 may include a bit line precharge circuit that precharges the bit lines BLs.

A row driver 14 may be connected to the memory cell block 11 through the word lines WLs. The row driver 14 may activate at least one of the word lines WLs based on a row address ROW. That is, the row driver 14 may select at least one of the word lines WLs based on the row address ROW. Accordingly, bit cells connected to the activated word line may be selected from among the plurality of bit cells 12.

The control block 15 may receive the command CMD, the address ADDR, and the clock CLK and may generate the row address ROW, the column address COL, and the control signal CTR. For example, the control block 15 may identify the read command by decoding the command CMD and may generate the row address ROW, the column address COL, and the control signal CTR to read the read data DATA_OUT from the memory cell block 11. In addition, the control block 15 may identify the write command by decoding the command CMD and may generate the row address ROW, the column address COL, and the control signal CTR to write the write data DATA_IN to the memory cell block 11.

FIG. 2 is a circuit diagram of a bit cell according to embodiments.

Referring to FIG. 2, a bit cell BC may include a first pass transistor PG1, a second pass transistor PG2, a read pass transistor RPG, a first pull-up transistor PU1, a second pull-up transistor PU2, a first pull-down transistor PD1, a second pulled-down transistor PD2, and a read pull-down transistor RPD.

In some embodiments, the bit cell BC may include the TPSRAM cell. The bit cell BC includes a write port WP and a read port RP, wherein the write port WP may operate in parallel with the read port RP. The write port WP may include the first pass transistor PG1, the second pass transistor PG2, the first pull-up transistor PU1, the second pull-up transistor PU2, the first pull-down transistor PD1, and the second pull-down transistor PD2. The first pull-up transistor PU1 and the second pull-up transistor PU2 may include P-type transistors, and the first pass transistor PG1, the second pass transistor PG2, the first pull-down transistor PD1, and the second pull-down transistor PD2 may include N-type transistors. For example, the first pull-up transistor PU1 and the second pull-up transistor PU2 may include P-channel metal-oxide-semiconductor field-effect transistors (MOSFETs) (PFETs), and the first pass transistor PG1, the second pass transistor PG2, the first pull-down transistor PD1, and the second pull-down transistor PD2 may include N-channel MOSFETs (NFETs).

In some embodiments, the first pull-up transistor PU1 and the first pull-down transistor PD1 may constitute a first inverter, and the second pull-up transistor PU2 and the second pull-down transistor PD2 may constitute a second inverter.

Specifically, a drain terminal of the first pull-up transistor PU1 may be connected to a drain terminal of the first pull-down transistor PD1, and a gate of the first pull-up transistor PU1 may be electrically connected to a gate of the first pull-down transistor PD1. A power supply voltage VDD may be applied to a source terminal of the first pull-up transistor PU1, and a ground voltage VSS may be applied to a source terminal of the first pull-down transistor PD1. Accordingly, the first pull-up transistor PU1 and the first pull-down transistor PD1 may constitute the first inverter.

Similarly, a drain terminal of the second pull-up transistor PU2 may be connected to a drain terminal of the second pull-down transistor PD2, and a gate of the second pull-up transistor PU2 may be electrically connected to a gate of the second pull-down transistor PD2. The power supply voltage VDD may be applied to a source terminal of the second pull-up transistor PU2, and the ground voltage VSS may be applied to a source terminal of the first pull-down transistor PD2. Accordingly, the second pull-up transistor PU2 and the second pull-down transistor PD2 may constitute the second inverter.

In some embodiments, the first pass transistor PG1 and the second pass transistor PG2 may control access, during the read and write operations, to a memory cell (e.g., bit cell BC) including the first inverter and the second inverter.

A gate of the first pull-up transistor PU1 and a gate of the first pull-down transistor PD1 connected to each other may correspond to an input terminal of the first inverter, and a first node N1 connected to the drain terminal of the first pull-up transistor PU1 and the drain terminal of the first pull-down transistor PD1 may correspond to an output terminal of the second inverter.

The gate of the second pull-up transistor PU2 and the gate of the second pull-down transistor PD2 connected to each other may correspond to an input terminal of the second inverter, and a second node N2 connected to the drain terminal of the second pull-up transistor PU2 and the drain terminal of the second pull-down transistor PD2 may correspond to an output terminal of the second inverter.

The first inverter and the second inverter may be coupled to each other in a latch structure. That is, the gate of the first pull-up transistor PU1 and the gate of the first pull-down transistor PD1 may be connected to the second node N2, and the gate of the second pull-up transistor PU2 and the gate of the second pull-down transistor PD2 may be connected to the first node N1. The first node N1 and the second node N2 may refer to complementary nodes at opposite logic levels (logic high or logic low).

The first node N1 may be connected to the first write bit line WBL of the write port WP through the first pass transistor PG1, and the second node N2 may be connected to the second write bit line WBLB of the write port WP through the second pass transistor PG2. The second write bit line WBLB may refer to a bit line complementary to the first write bit line WBL. For example, a drain terminal of the first pass transistor PG1 may be connected to the first node N1. A source terminal of the first pass transistor PG1 may be connected to the first write bit line WBL. A drain terminal of the second pass transistor PG2 may be connected to the second node N2. A source terminal of the second pass transistor PG2 may be connected to the second write bit line WBLB. The gates of the first pass transistor PG1 and the second pass transistor PG2 may be connected to a write word line WWL of the write port WP.

In some embodiments, the read port RP of the bit cell BC may include the read pass transistor RPG and the read pull-down transistor RPD. A gate of the read pass transistor RPG may be connected to a read word line RWL of the read port RP. A gate of the read pull-down transistor RPD may be connected to the second node N2. The read pass transistor RPG and the read pull-down transistor RPD may be connected between the read bit line RBL of the read port RP and the ground voltage RVSS. For example, a drain terminal of the read pass transistor RPG may be connected to the read bit line RBL of the read port RP, and the ground voltage RVSS may be applied to a source terminal of the read pull-down transistor RPD.

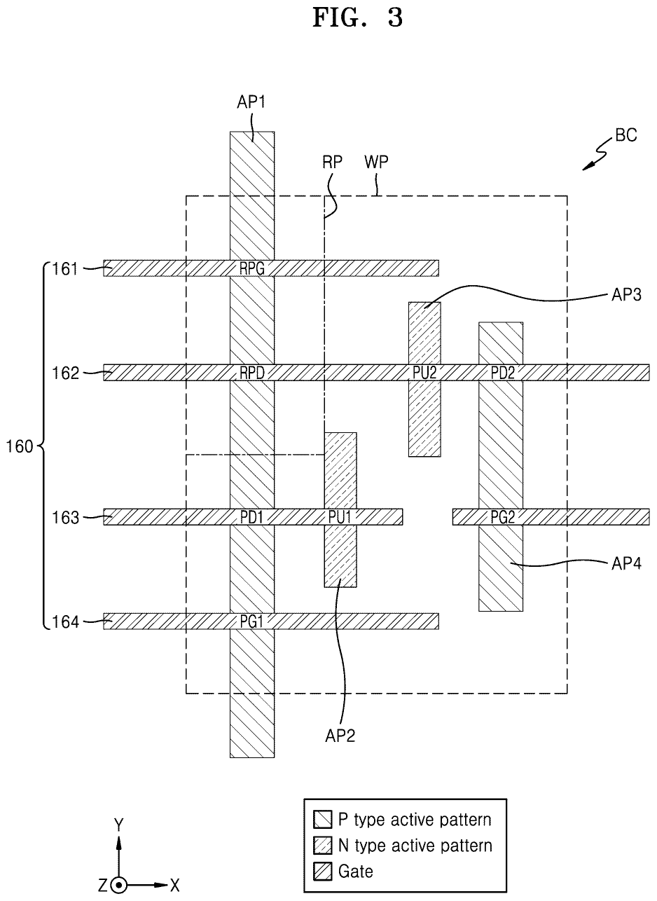

FIGS. 3 to 6 are layout diagrams of the bit cell according to embodiments.

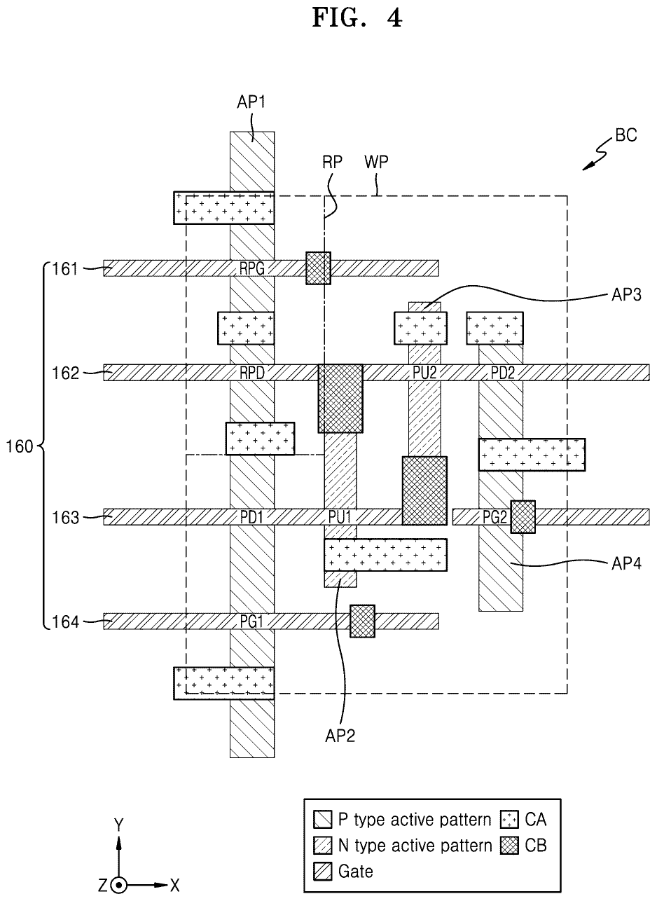

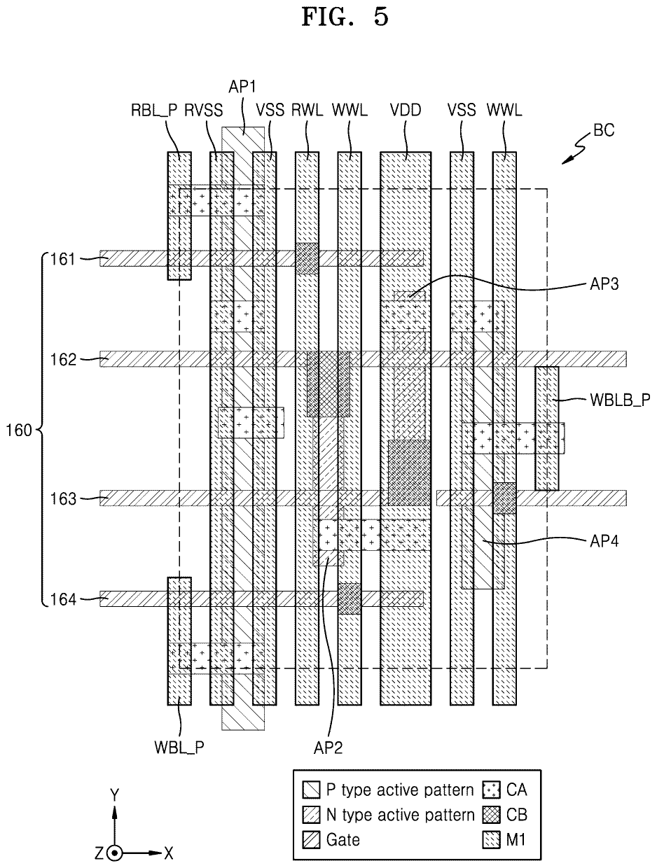

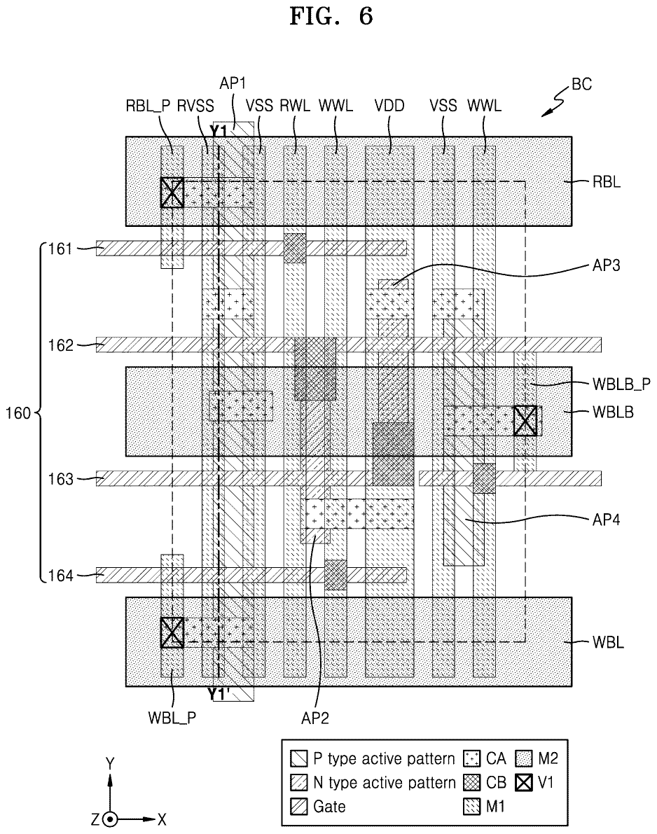

Specifically, FIG. 3 is a layout diagram of the bit cell BC schematic illustrating only a plurality of gates 160 and first to fourth active regions AP1, AP2, AP3, and AP4, according to some embodiments. FIG. 4 is a layout diagram of the bit cell BC where a plurality of source/drain contacts CA and a plurality of gate contacts CB are added to the layout diagram of FIG. 3. FIG. 5 is a layout diagram of the bit cell BC where first wiring layers M1 are added to the layout diagram of FIG. 4. FIG. 6 is a layout diagram of the bit cell BC where second wiring layers M2 are added to the layout diagram of FIG. 5.

Referring to FIGS. 3 and 6, the bit cell BC may include the TPSRAM cell including the write port WP and the read port RP. The bit cell BC may include the first to fourth active regions AP1, AP2, AP3, and AP4 spaced apart from each other in parallel in a first direction (X direction) and extending in a second direction (Y direction) perpendicular to the first direction (X direction). In the inventive concept, one bit cell BC may include four active regions, e.g., the first active region AP1, the second active region AP2, the third active region AP3, and the fourth active region AP4.

In some embodiments, each of the first active region AP1, the second active region AP2, the third active region AP3, and the fourth active region AP4 may include a P-type active pattern where N-type transistors are formed or an N-type active pattern where P-type transistors are formed. For example, the first active region AP1 and the fourth active region AP4 may include the P-type active pattern, and the second active region AP2 and the third active region AP3 may include the N-type active pattern.

The first active region AP1, the second active region AP2, the third active region AP3, and the fourth active region AP4 may have different widths in the first direction (X direction). For example, widths of the first active region AP1 and the fourth active region AP4 in the first direction (X direction) may be greater than widths of the second active region AP2 and the third active region AP3 in the first direction (X direction), but the inventive concept is not limited thereto.

A plurality of transistors may be formed in the first active region AP1, the second active region AP2, the third active region AP3, and the fourth active region AP4. The plurality of transistors may include, but are not limited to, a fin field effect FET (FinFET) formed by a gate electrode and an active pattern extending in a fin shape, a gate-all-around FET (GAAFET) formed by the gate electrode and a plurality of nanowires extending in parallel to each other, or a multi-bridge channel FET (MBCFET) formed by the gate electrode and a plurality of nanosheets extending in parallel to each other.

In some embodiments, the bit cell BC may include the plurality of gates 160 spaced apart from each other in parallel in the second direction (Y direction) and extending in the first direction (X direction). The plurality of gates 160 may partially overlap with the one or more active regions AP1, AP2, AP3, and AP4. The plurality of gates 160 may include a structure corresponding to gate ends of transistors formed in the first to fourth active regions AP1, AP2, AP3, and AP4. That is, the plurality of gates 160 and the first to fourth active regions AP1, AP2, AP3, and AP4 may form the transistors.

In some embodiments, a first gate 161, a second gate 162, a third gate 163 and a fourth gate 164 may be formed on the first active region AP1. The first gate 161, the second gate 162, the third gate 163, and the fourth gate 164 may be spaced apart from each other in parallel in the second direction (Y direction) and may extend in the first direction (X direction) on the first active region AP1. Some gates (e.g., the third gate 163) may include partially discontinuous portions.

In some embodiments, the first active region AP1 and the first gate 161 may form the read pass transistor RPG. The first active region AP1 and the second gate 162 may form the read pull-down transistor RPD. The first active region AP1 and the third gate 163 may form the first pull-down transistor PD1. The first active region AP1 and the fourth gate 164 may form the first pass transistor PG1.

In some embodiments, a portion of the first active region AP1 may be arranged in the read port RP, and a portion of the second active region AP1 may be arranged in the write port WP. That is, the first active region AP1 may be shared by the read port RP and the write port WP.

The read port RP and the write port WP may share the first active region AP1 so that the read pass transistor RPG, the read pull-down transistor RPD, the first pass transistor PG1, and the first pull-down transistor PD1 may share the first active region AP1. Since the first active region AP1 is the P-type active pattern, the read pass transistor RPG, the read pull-down transistor RPD, the first pass transistor PG1, and the first pull-down transistor PD1 may all include the N-type transistors.

In the write port WP, the second active region AP2, the third active region AP3, and the fourth active region AP4 may be spaced apart from each other in parallel in the first direction (X direction) and may extend in the second direction (Y direction). The third gate 163 may be arranged on the second active region AP2, and the third gate 163 and the second active region AP2 may form the first pull-up transistor PU1. The second gate 162 may be arranged on the third active region AP3, and the second gate 162 and the third active region AP3 may form the second pull-up transistor PU2. The second gate 162 may be arranged on the fourth active region AP4, and the second gate 162 and the fourth active region AP4 may form the second pull-down transistor PD2. The third gate 163 may be arranged on the fourth active region AP4, and the third gate 163 and the fourth active region AP4 may form the second pass transistor PG2.

In some embodiments, the bit cell BC of the inventive concept may include four active regions, that is, the first, second, third, and fourth active regions AP1, AP2, AP3, and AP4, and four gates, that is, the first, second, third, and fourth gates 161, 162, 163, and 164. The read pass transistor RPG and the read pull-down transistor RPD of the read port RP and the first pass transistor PG1 and the first pull-down transistor PD1 of the write port WP may share the first active region AP1. Therefore, the area of the bit cell BC may be reduced compared to the comparative example in which the read pass transistor RPG and the read pull-down transistor RPD of the read port RP and the first pass transistor PG1 and the first pull-down transistor PD1 of the write port WP are arranged on different active regions. For example, the area of the bit cell BC may be reduced by about 10%, compared to the comparative example including five active regions and two gates.

In addition, since the read pass transistor RPG, the read pull-down transistor RPD, the first pass transistor PG1, and the first pull-down transistor PD1 share the first active region AP1, the pattern loading effect generated during the process may also be reduced. The pattern loading effect may refer to a phenomenon where the pattern density and size are non-uniformly formed during etching and deposition processes. Therefore, the electrical performance of the bit cell BC of the inventive concept may be improved

Referring to FIGS. 4 and 5, a voltage may be applied to the plurality of gates 160 through the plurality of gate contacts CB. The plurality of gates 160 may include a conductive material. For example, the plurality of gates 160 may include at least one of a semiconductor material (e.g., doped silicon (Si), doped germanium (Ge), or doped silicon-germanium (SeGe)), a metal (e.g., tungsten (W) or aluminum (Al)), a metal compound (e.g., metal silicide), a conductive metal nitride (e.g., titanium nitride (TiN), tantalum nitride (TaN), or tungsten nitride (WN)), or a transition metal (e.g., titanium (Ti) or tantalum (Ta)).

A plurality of source/drain contacts CA may be formed on the first to fourth active regions AP1, AP2, AP3, and AP4. The plurality of source/drain contacts CA may extend in the first direction (X direction). The plurality of source/drain contacts CA may provide a voltage to a source region and a drain region of the transistor.

The plurality of gate contacts CB and the plurality of source/drain contacts CA may each be electrically connected to the first wiring layers M1. The first wiring layers M1 may be spaced apart from the plurality of gates 160 and the first to fourth active regions AP1, AP2, AP3, and AP4 in the vertical direction (Z direction). The plurality of gate contacts CB may electrically connect the plurality of gates 160 to the first wiring layers M1, and the plurality of source/drain contacts CA may electrically connect the first to fourth active regions AP1, AP2, AP3, and AP4 to the first wiring layers M1. The sum of heights of the gate 160 and the gate contact CB may be equal to the height of the source/drain contact CA, but the inventive concept is not limited thereto.

The first wiring layers M1 may be spaced apart from each other in parallel in the first direction (X direction) and may extend in the second direction (Y direction). The first wiring layers M1 may include a plurality of metal lines. For example, the first wiring layers M1 may include a read ground voltage line RVSS, a write ground voltage line VSS, a read word line RWL, a write word line WWL, a write power supply voltage line VDD, a read bit line pad RBL_P, and first and second write bit line pads WBL_P and WBLB_P.

In some embodiments, the read ground voltage line RVSS may be connected to the source terminal of the read pull-down transistor RPD of the read port RP through the source/drain contact CA. The write ground voltage line VSS may be connected to source terminals of the first pull-down transistor PD1 and the second pull-down transistor PD2 of the write port WP through the source/drain contact CA. The write power supply voltage line VDD may be connected to source terminals of the first pull-up transistor PU1 and the second pull-up transistor PU2 of the write port WP through the source/drain contact CA. The read bit line pad RBL_P may be connected to the drain terminal of the read pass transistor RPG of the read port RP through the source/drain contact CA. The first write bit line pad WBL_P and the second write bit line pad WBLB_P may be respectively connected to the source terminal of the first pass transistor PG1 and the source terminal of the second pass transistor PG2 through the source/drain contact CA.

In some embodiments, the read word line RWL may be connected to the gate (e.g., the first gate 161) of the read pass transistor RPG of the read port RP through the gate contact CB. The write word line WWL may be connected to the gates (e.g., the fourth gate 164 and the third gate 163) of the first pass transistor PG1 and the second pass transistor PG2 of the write port WP through the gate contact CB.

In some embodiments, the read word line RWL and the write word line WWL may extend in the second direction (Y direction). That is, the read word line RWL and the write word line WWL may extend in a direction parallel to the first to fourth active regions AP1, AP2, AP3, and AP4 and perpendicular to the plurality of gates 160.

In some embodiments, the lengths of the read bit line pad RBL_P and the first and second write bit line pads WBL_P and WBLB_P in the second direction (Y direction) may be less than those of the other metal lines of the first wiring layers M1. For example, the lengths of the read bit line pad RBL_P and the first and second write bit line pads WBL_P and WBLB_P in the second direction (Y direction) may be less than those of the read word line RWL and the write word line WWL.

Referring to FIG. 6, the second wiring layers M2 may be disposed on the first wiring layers M1. That is, the vertical level of the second wiring layers M2 may be greater than that of the first wiring layers M1. The second wiring layers M2 may be spaced apart from each other in parallel in the second direction (Y direction) and may extend in the first direction (X direction). The first wiring layer M1 may be electrically connected to the second wiring layer M2 through a connection via V1. That is, the first wiring layer M1 and the second wiring layer M2 may be spaced apart from each other in the vertical direction (Z direction) with the connection via V1 therebetween.

In some embodiments, the second wiring layers M2 may include a plurality of metal lines. For example, the second wiring layers M2 may include the read bit line RBL, the first write bit line WBL, and the second write bit line WBLB. The second write bit line WBLB may refer to a bit line complementary to the first write bit line WBL. The read bit line RBL may be electrically connected to the read bit line pad RBL_P through the connection via V1. The first write bit line WBL may be electrically connected to the first write bit line pad WBL_P through the connection via V1. The second write bit line WBLB may be electrically connected to the second write bit line pad WBLB_P through the connection via V1.

In some embodiments, the read bit line RBL, the first write bit line WBL, and the second write bit line WBLB may extend in the first direction (X direction). That is, the read bit line RBL, the first write bit line WBL, and the second write bit line WBLB may extend in a direction parallel to the plurality of gates 160 and perpendicular to the first to fourth active regions AP1, AP2, AP3, and AP4.

In some embodiments, the thicknesses of the read bit line RBL, the first write bit line WBL, and the second write bit line WBLB in the second direction (Y direction) may be greater than those of the other metal lines of the first wiring layers M1. For example, the thicknesses of the read bit line RBL, the first write bit line WBL, and the second write bit line WBLB in the second direction (Y direction) may be greater than those of the read word line RWL and the write word line WWL in the first direction (X direction).

In some embodiments, as the second wiring layers M2 on the first wiring layers M1 include the read bit line RBL, the first write bit line WBL, and the second write bit line WBLB, the read bit line RBL, first write bit line WBL, and second write bit line WBLB may be designed to be thick. As the thicknesses of the read bit line RBL, the first write bit line WBL, and the second write bit line WBLB in the second direction (Y direction) increase, the bit line capacitance may decrease. Therefore, the electrical performance of the bit cell BC of the inventive concept may be improved.

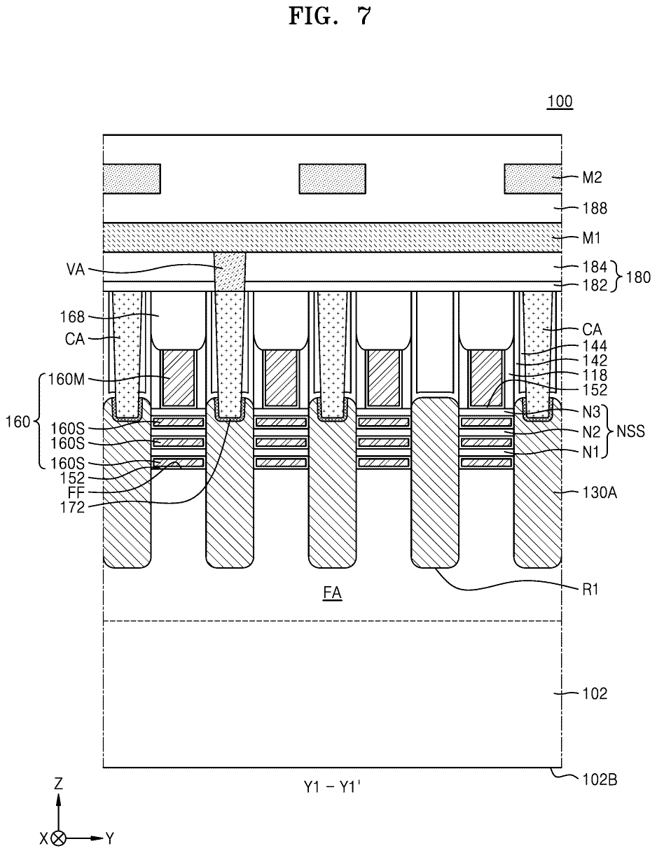

FIG. 7 is a cross-sectional view of an integrated circuit device 100 according to some embodiments. Specifically, FIG. 7 is a cross-sectional view taken along line Y1-Y1′ in FIG. 6.

Referring to FIG. 7, the integrated circuit device 100 may include a fin-type active region FA protruding from a substrate 102 and extending in the second direction (Y direction). The substrate 102 may include a conductive region, e.g., an impurity-doped well or an impurity-doped structure. The fin-type active region FA may correspond to the first active region AP1 in FIG. 6.

A plurality of nanosheet stacks NSS may be disposed on a front-side surface FF of the fin-type active region FA. The plurality of nanosheet stacks NSS may each include at least one nanosheet. As used herein, the term “nanosheet” refers to a conductive structure having a cross-section substantially perpendicular to a direction in which current flows. It should be understood that the nanosheet includes nanowires.

Although a configuration in which the plurality of nanosheet stacks NSS include a first nanosheet N1, a second nanosheet N2, and a third nanosheet N3 is illustrated herein, the number of nanosheets included in each of the plurality of nanosheet stacks NSS may be variously changed. For example, the plurality of nanosheet stacks NSS may each include at least one nanosheet or at least two nanosheets, and the number of nanosheets constituting the nanosheet stack NSS is not particularly limited. The first to third nanosheets N1, N2, and N3 may each have a channel region. In some embodiments, the first to third nanosheets N1, N2, and N3 included in the nanosheet stack NSS may each include a Si layer, a SiGe layer, or a combination thereof.

In some embodiments, the first to third nanosheets N1, N2, and N3 may each have a vertical thickness selected from a range of about 4 nm to about 6 nm. In some embodiments, the first to third nanosheets N1, N2, and N3 may have substantially the same thickness. The first to third nanosheets N1, N2, and N3 may include the same material.

The integrated circuit device 100 may include a plurality of source/drain regions 130A. The plurality of source/drain regions 130A may be arranged one by one at positions adjacent to the plurality of nanosheet stacks NSS on both sides of each of the plurality of nanosheet stacks NSS in the second direction (Y direction). The plurality of source/drain regions 130A disposed on the fin-type active region FA may be spaced apart from each other in the second direction (Y direction). The plurality of source/drain regions 130A may each be in contact with the first to third nanosheets N1, N2, and N3 included in the adjacent nanosheet stack NSS. Herein, each of the plurality of source/drain regions 130A may be referred to as an N-type semiconductor region.

In some embodiments, the plurality of source/drain regions 130A may each consist of a Si layer doped with an N-type dopant or a silicon carbide (SiC) layer doped with an N-type dopant. The n-type dopant may be selected from phosphorus (P), arsenic (As), and antimony (Sb).

The integrated circuit device 100 may include the plurality of gates 160. The plurality of gates 160 may each cover the fin-type active region FA. The plurality of gates 160 may have substantially the same configuration as the plurality of gates 160 described with reference to FIGS. 3 to 6. The plurality of gates 160 may be spaced apart from each other in the second direction (Y direction) and extend lengthwise in the first direction (X direction). The plurality of gates 160 may each wrap the first to third nanosheets N1, N2, and N3 included in the nanosheet stack NSS overlapping with the plurality of gates 160 in the vertical direction (Z direction).

Each of the plurality of gates 160 may include a metal, a metal nitride, a metal carbide, or a combination thereof. The metal may be selected from Ti, W, ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from TiN and TaN. The metal carbide may be TiAlC. However, the materials constituting the plurality of gates 160 are not limited to the above.

The plurality of gates 160 may each include a main gate portion 160M covering a top surface of the nanosheet stack NSS and extending in the first direction (X direction), and a plurality of sub-gate portions 160S integrally connected to the main gate portion 160M and arranged in a space between each of the first to third nanosheets N1, N2, and N3 and a space between the front-side surface FF and the first nanosheet N1. In the vertical direction (Z direction), the thickness of each of the plurality of sub-gate portions 160S may be less than the thickness of the main gate portion 160M. The second and third nanosheets N2 and N3, without the first nanosheet N1, among the first to third nanosheets N1, N2, and N3 may have a gate-all-around (GAA) structure completely surrounded by the gate 160.

A gate dielectric film 152 may be arranged between the nanosheet stack NSS and the gate 160. The gate dielectric film 152 may have a stack structure of an interface dielectric film and a high-k film. The interface dielectric film may include a low-k material film having a dielectric constant of about 9 or less, such as a silicon oxide film, a silicon oxynitride film, or a combination thereof. In some embodiments, the interface dielectric film may be omitted. The high-k film may include a material having a dielectric constant greater than that of the silicon oxide film. For example, the high-k film may have a dielectric constant of about 10 to about 25. The high-k film may include hafnium oxide, but is not limited thereto.

Both sidewalls of each of the plurality of sub-gate portions 160S included in the plurality of gates 160 may be spaced apart from the source/drain region 130A with the gate dielectric film 152 therebetween. The gate dielectric film 152 may be arranged between the sub-gate portion 160S included in the gate 160 and each of the first to third nanosheets N1, N2, and N3, and between the sub-gate portion 160S included the gate 160 and the source/drain region 130A. The plurality of gates 160, the plurality of nanosheet stacks NSS, and the source/drain region 130A may constitute a plurality of nanosheet transistors.

Both sidewalls of the gate 160 may be covered with a plurality of insulating spacers 118. The plurality of insulating spacers 118 may each cover a sidewall of the main gate portion 160M above the top surface of the nanosheet stack NSS. Each of the plurality of insulating spacers 118 may be spaced apart from the gate 160 with the gate dielectric film 152 therebetween. The plurality of insulating spacers 118 may each consist of silicon nitride, silicon oxide, SiOC, SiOCN, SiCN, SiBN, SiON, SiBCN, SiOF, SiOCH, or a combination thereof. The plurality of insulating spacers 118 may include a single film including one material film selected from the materials listed above or may include a multi-film including a plurality of material films selected from the materials list above.

A top surface of each of the gate 160, the gate dielectric film 152, and the insulating spacer 118 may be covered with a capping insulating pattern 168. The capping insulating pattern 168 may include a silicon nitride film.

The plurality of source/drain regions 130A and the plurality of insulating spacers 118 may be covered with an insulating liner 142. An inter-gate insulating film 144 may be disposed on the insulating liner 142. The inter-gate insulating film 144 may fill a space between a pair of gates 160 adjacent to each other in the second direction (Y direction). In some embodiments, the insulating liner 142 may include silicon nitride, SiCN, SiBN, SiON, SiOCN, SiBCN, or a combination thereof, and the inter-gate insulating film 144 may include a silicon oxide film but is not limited thereto.

The plurality of source/drain contacts CA may be disposed above the plurality of source/drain regions 130A. Each of the plurality of source/drain contacts CA may be configured to be electrically connected to at least one of the plurality of source/drain regions 130A. A metal silicide film 172 may be arranged between the source/drain region 130A and the source/drain contact CA. The metal silicide film 172 may be in contact with the corresponding source/drain region 130A. The source/drain contact CA may pass through the inter-gate insulating film 144 and the insulating liner 142 in the vertical direction (Z direction) to be in contact with the metal silicide film 172. The source/drain contact CA may be configured to be connected to the source/drain region 130A through the metal silicide film 172. The source/drain contact CA may pass through a portion of the source/drain region 130A in the vertical direction (Z direction). The insulating liner 142 and the inter-gate insulating film 144 may surround a sidewall of the source/drain contact CA.

In some embodiments, the metal silicide film 172 may include Ti, W, Ru, Nb, Mo, Hf, Ni, Co, Pt, Yb, Tb, Dy, Er, or Pd. For example, the metal silicide film 172 may include titanium silicide. In some embodiments, the source/drain contact CA may include only a metal plug consisting of a single metal. In some embodiments, the source/drain contact CA may include the metal plug and a conductive barrier film surrounding the metal plug. The conductive barrier film may include a metal or a conductive metal nitride.

The top surface of each of the source/drain contact CA, the plurality of capping insulating patterns 168, and the inter-gate insulating film 144 may be covered with an upper insulating structure 180. The upper insulating structure 180 may include an etching stop film 182 and an upper insulating film 184 sequentially stacked on each of the plurality of source/drain contacts CA, the plurality of capping insulating patterns 168, and the inter-gate insulating film 144. The etching stop film 182 may include SiC, SiN, SiCN, SiOC, AlN, AlON, AlO, AlOC, or a combination thereof. The upper insulating film 184 may include an oxide film, a nitride film, an ultra-low k (ULK) film having an ultra-low dielectric constant of about 2.2 to about 2.4, or a combination thereof.

A source/drain via contact VA may be placed on the source/drain contact CA. The source/drain via contact VA may pass through the upper insulating structure 180 and may be in contact with the source/drain contact CA.

The first wiring layers M1 may be disposed on the upper insulating structure 180. An interlayer insulating film 188 may be arranged between the first wiring layers M1 in the first direction (X direction). The first wiring layers M1 may be connected to the source/drain contact CA and the gate contact CB through the source/drain via contact VA and a gate via contact. As shown in FIG. 6, the first wiring layers M1 may include the read ground voltage line RVSS, the write ground voltage line VSS, the read word line RWL, the write word line WWL, the write power supply voltage line VDD, the read bit line pad RBL_P, and the first and second write bit line pads WBL_P and WBLB_P. The plurality of gate contacts CB may electrically connect the plurality of gates 160 to the first wiring layers M1, and the plurality of source/drain contacts CA may electrically connect the first to fourth active regions AP1, AP2, AP3, and AP4 to the plurality of the first wiring layers M1.

The second wiring layers M2 may be disposed on the first wiring layers M1. The second wiring layers M2 may include a plurality of bit lines. The interlayer insulating film 188 may cover the second wiring layers M2.

The first wiring layers M1 and the second wiring layers M2 may include, but are not limited to, Mo, copper (Cu), W, Co, Ru, manganese (Mn), Ti, Ta, Al, a combination thereof, or an alloy thereof. The constituent material of the interlayer insulating film 188 is substantially the same as the aforementioned constituent material of the upper insulating film 184.

Referring to FIG. 6 together, the source/drain region 130A constituting the read pass transistor RPG may be connected to the read bit line RBL through the source/drain contact CA and the read bit line pad RBL_P, and the source/drain region 130A constituting the read pull-down transistor RPD may be connected to the read ground voltage line RVSS through the source/drain contact CA. In addition, the source/drain region 130A constituting the first pull-down transistor PD1 may be connected to the write ground voltage line VSS of the write port through the source/drain contact CA, and the source/drain region 130A constituting the first pass transistor PG1 may be connected to the first write bit line WBL through the source/drain contact CA and the first write bit line pad WBL_P.

In some embodiments, the integrated circuit device 100 may form the read pass transistor RPG and the read pull-down transistor RPD of the read port RP and the first pass transistor PG1 and the first pull-down transistor PD1 of the write port WP on one fin-type active region FA. Therefore, the area of the integrated circuit device 100 may be reduced, compared to the comparative example in which the read pass transistor RPG and the read pull-down transistor RPD of the read port RP and the first pass transistor PG1 and the first pull-down transistor PD1 of the write port WP are arranged on different active regions. Therefore, the degree of integration of the integrated circuit device 100 may be improved.

In addition, by arranging a plurality of bit lines in the second wiring layer M2 on the first wiring layers M1, the bit lines may be designed to be thick. Accordingly, the bit line capacitance may be reduced to improve the electrical performance of the integrated circuit device 100.

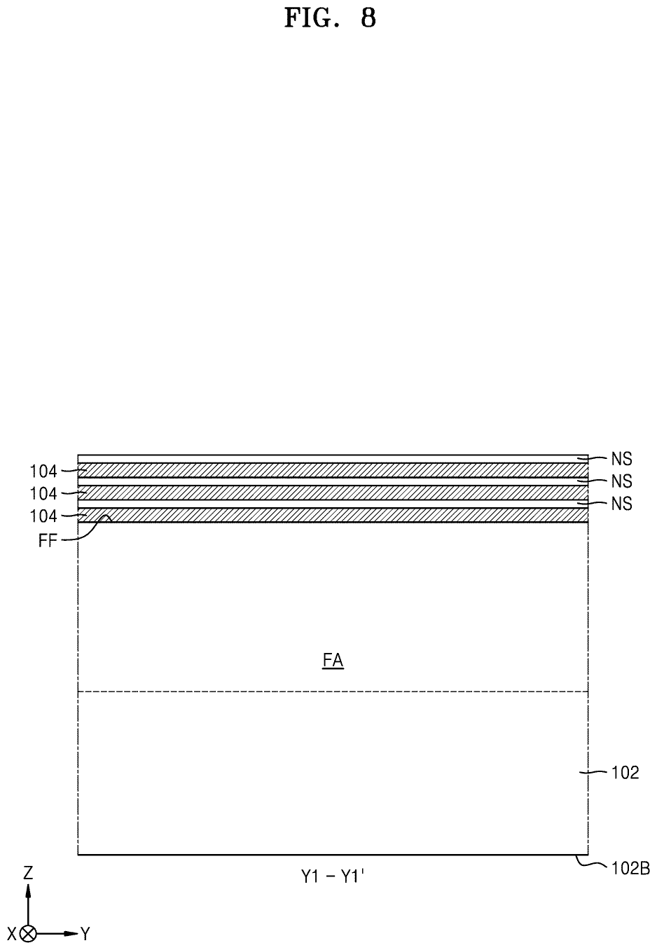

FIGS. 8 to 12 are cross-sectional views of a portion of the integrated circuit device 100 taken along line Y1-Y1′ of FIG. 6 to illustrate a method of manufacturing the integrated circuit device 100 in accordance with a process sequence, according to an embodiment.

Referring to FIG. 8, a stack structure in which a plurality of sacrificial semiconductor layers 104 and a plurality of nanosheet semiconductor layers NS are alternately stacked one by one may be formed on the substrate 102. In the stack structure, the plurality of sacrificial semiconductor layers 104 and the plurality of nanosheet semiconductor layers NS may include semiconductor materials having different etching selectivities. In some embodiments, the plurality of nanosheet semiconductor layers NS may include a Si layer, and the plurality of sacrificial semiconductor layers 104 may include an SiGe film. The SiGe film constituting the sacrificial semiconductor layer 104 may have a Ge content ratio selected from a range of about 5 at % to about 50 at %, for example, about 10 at % to about 40 at %.

The fin-type active region FA may be formed by forming a mask pattern having openings partially exposing the top surface of the stack structure, and etching a portion of each of the plurality of sacrificial semiconductor layers 104, the plurality of nanosheet semiconductor layers NS, and the substrate 102 using the mask pattern as an etching mask. In this case, the fin-type active region FA may correspond to the first active region AP1 in FIGS. 3 to 6.

A plurality of trench regions may be defined on the substrate 102 by the fin-type active region FA. The plurality of sacrificial semiconductor layers 104 and the plurality of nanosheet semiconductor layers NS may remain on the front-side surface FF of the fin-type active region FA. Then, a device isolation film may be formed to fill the plurality of trench regions and cover the sidewalls of the fin-type active region FA.

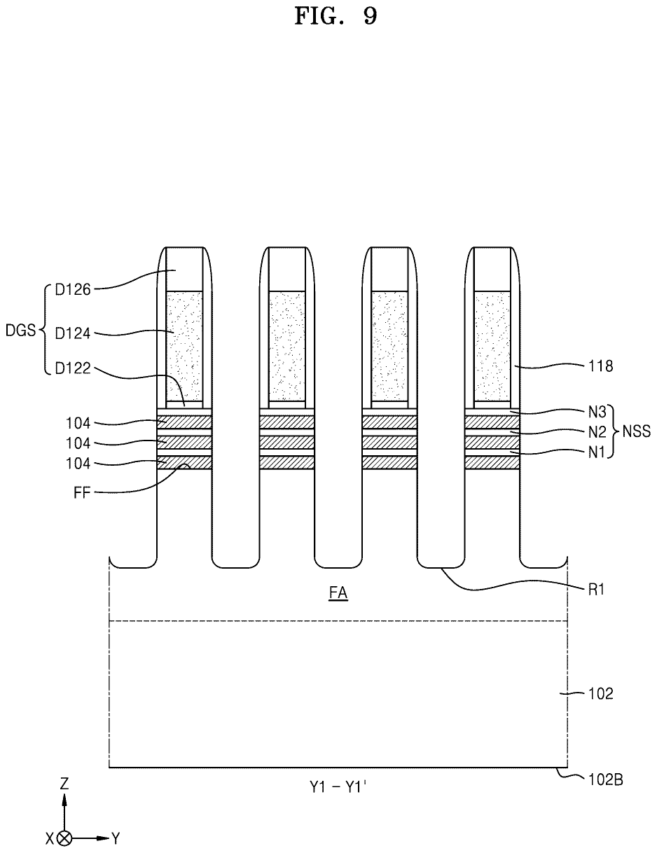

Referring to FIG. 9, a plurality of dummy gate structures DGS may be formed on the resultant of FIG. 8. Each of the plurality of dummy gate structures DGS may extend lengthwise in the first direction (X direction). Each of the plurality of dummy gate structures DGS may include a dummy oxide film D122, a dummy gate layer D124, and a capping layer D126 sequentially stacked on the stack structure including the plurality of sacrificial semiconductor layers 104 and the plurality of nanosheet semiconductor layers NS. In some embodiments, the dummy gate layer D124 may include polysilicon, and the capping layer D126 may include a silicon nitride film.

The plurality of nanosheet semiconductor layers NS may be divided into the plurality of nanosheet stacks NSS including first to third nanosheets N1, N2, and N3 by forming the plurality of insulating spacers 118 covering both sidewalls of each of the plurality of dummy gate structures DGS, and etching a portion of each of the plurality of sacrificial semiconductor layers 104 and the plurality of nanosheet semiconductor layers NS and a portion of the fin-type active region FA by using the plurality of dummy gateway structures DGS and the plurality of insulating spacer 118 as an etching mask.

Then, a plurality of recesses R1 may be formed above each of the fin-type active regions FA. Each of the first to third nanosheets N1, N2, and N3 may have a width defined by the plurality of recesses R1 in the second direction (Y direction). Etching may be performed using dry etching, wet etching, or a combination thereof to form the plurality of recesses R1.

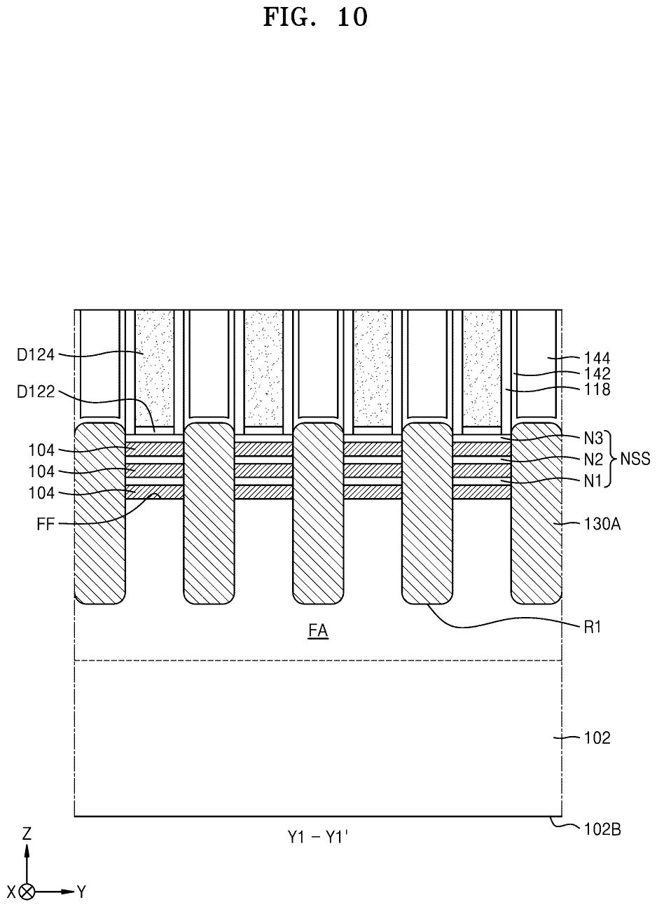

Referring to FIG. 10, the plurality of source/drain regions 130A filling the plurality of recesses R1 may be formed in the resultant of FIG. 9. To form the plurality of source/drain regions 130A, a semiconductor material may be epitaxially grown from the sidewall of each of the first to third nanosheets N1, N2, and N3 exposed in the plurality of recesses R1 and the surface of the fin-type active region FA.

Thereafter, a portion of each of the insulating liner 142 and the inter-gate insulation film 144 may be etched to expose the top surfaces of the plurality of capping layers D126 (see FIG. 9) after forming the insulating liner 142 covering the plurality of source/drain regions 130A and forming the inter-gate insulating film 144 on the insulating liner 142. Thereafter, the plurality of capping layers D126 may be removed to expose the dummy gate layer D124, and the insulating liner 142 and the inter-gate insulating film 144 may be partially removed such that the top surface of the inter-gate insulation film 144 and the top surface of the dummy gate layer D224 are at substantially the same level.

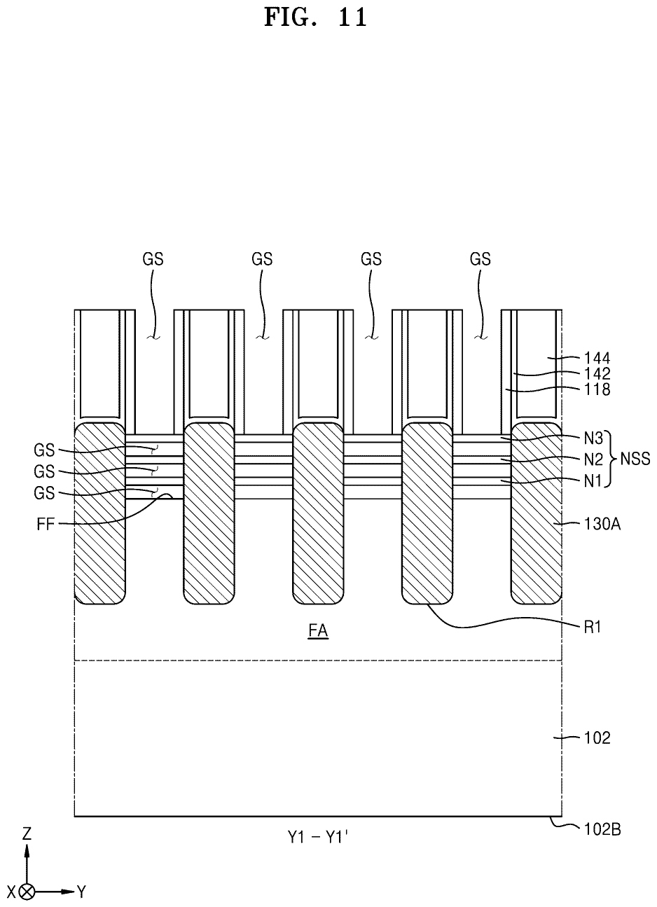

Referring to FIG. 11, the dummy gate layer D124 and the dummy oxide film D122 may be removed from the resultant of FIG. 10 to form a gate structure GS. The plurality of sacrificial semiconductor layers 104 remaining on the substrate 102 may then be selectively removed through the gate structure GS to extend the gate structure GS to the space between each of the first to third nanosheets N1, N2, and N3 and the space between the first nanosheet N and the front-side surface FF.

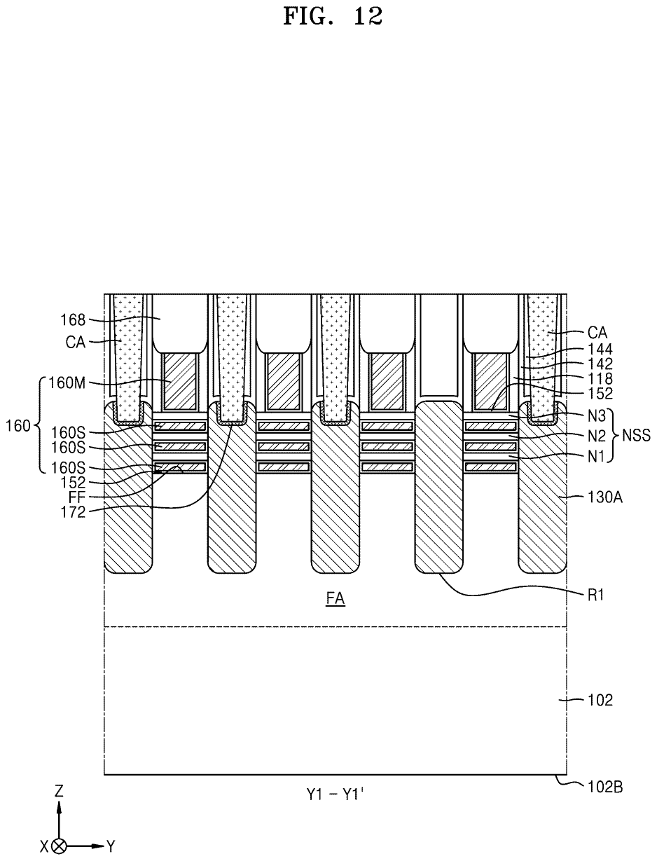

Referring to FIG. 12, the gate dielectric film 152 covering the exposed surfaces of each of the first to third nanosheets N1, N2, and N3 and the fin-type active region FA may be formed in the resultant of FIG. 11. An atomic layer deposition (ALD) process may be used to form the gate dielectric film 152.

Then, the gate 160 filling the gate structure GS (see FIG. 11) may be formed over the gate dielectric film 152. Then, a portion of each of the gate 160, the gate dielectric film 152, and the insulating spacer 118 may be removed from the top surface thereof to lower the height thereof, thereby forming the plurality of capping insulating patterns 168 covering the top surface of each of the gate 160, the gate dielectric film 152, and the insulating spacer 118.

Then, a source/drain contact hole exposing the plurality of source/drain regions 130A may be formed between two adjacent gates 160 among the plurality of gates 160, the metal silicide film 172 may be formed on a surface of the plurality of source/drain regions 130A through the source/drain contacting hole, and the plurality of source-drain contacts CA filling the source/drain contacting hole may be formed on the metal silicide film 172.

Referring back to FIG. 7, in the resultant of FIG. 12, the etching stop film 182 and the upper insulating film 184 covering the top surface of each of the source/drain contact CA, the plurality of capping insulating patterns 168, and the inter-gate insulating film 144 may be sequentially formed to form the upper insulating structure 180. Thereafter, the plurality of source/drain via contacts VA penetrating the upper insulating structure 180 in the vertical direction (Z direction) and connected to the source/drain contact CA, and the plurality of gate contacts CB (see FIG. 6) penetrating the upper insulating structure 180 and the capping insulating pattern 168 in the vertical direction (Z direction) and connected to the gate 160 may be formed. Then, the first wiring layers M1 may be formed on the upper insulating structure 180, and the second wiring layers M2 may be formed on the first wiring layers M1.

While the inventive concept has been particularly shown and described with reference to embodiments thereof, it will be understood that various changes in form and details may be made therein without departing from the spirit and scope of the following claims.

What is claimed is:

1. A bit cell including a read port and a write port, comprising:
a plurality of active regions spaced apart from each other in parallel in a first direction and extending in a second direction perpendicular to the first direction; and
a plurality of gates spaced apart from each other in parallel in the second direction, extending in the first direction, and arranged in at least one of the plurality of active regions to each form a transistor,
wherein the read port comprises a read pass transistor and a read pull-down transistor,
the write port comprises a first pass transistor, a second pass transistor, a first pull-down transistor, a second pull-down transistor, a first pull-up transistor, and a second pull-up transistor, and
the read pass transistor, the read pull-down transistor, the first pass transistor, and the first pull-down transistor share one active region.

2. The bit cell of claim 1, wherein the read pass transistor, the read pull-down transistor, the first pull-down transistor, and the first pass transistor comprise N-type transistors.

3. The bit cell of claim 1, wherein the plurality of active regions comprise a first active region, a second active region, a third active region, and a fourth active region,
the plurality of gates comprise a first gate, a second gate, a third gate, and a fourth gate,
the first active region and the first gate form the read pass transistor,
the first active region and the second gate form the read pull-down transistor,
the first active region and the third gate form the first pull-down transistor, and
the first active region and the fourth gate form the first pass transistor.

4. The bit cell of claim 3, wherein the second active region and the third gate form the first pull-up transistor,
the third active region and the second gate form the second pull-up transistor,
the fourth active region and the second gate form the second pull-down transistor, and
the fourth active region and the third gate form the second pass transistor.

5. The bit cell of claim 4, wherein the first pull-up transistor and the second pull-up transistor comprise P-type transistors, and
the second pull-down transistor and the second pass transistor comprise N-type transistors.

6. The bit cell of claim 1, further comprising a first wiring layer arranged on the plurality of gates and including a plurality of metal lines spaced apart from each other in parallel in the first direction and extending in the second direction, wherein the first wiring layer comprises a read word line connected to the read port and a write word line connected to the write port.

7. The bit cell of claim 6, wherein the first wiring layer comprises a read bit line pad connected to the read port and a write bit line pad connected to the write port, and
lengths of the read bit line pad and the write bit line pad in the second direction are less then lengths of the read word line and the write word line in the second direction.

8. The bit cell of claim 7, further comprising a second wiring layer arranged on the first wiring layer and including a plurality of metal lines spaced apart from each other in parallel in the second direction and extending in the first direction, wherein the second wiring layer further comprises a read bit line connected to the read bit line pad and a write bit line connected to the write bit line pad.

9. The bit cell of claim 8, wherein thicknesses of the read bit line and the write bit line in the second direction are greater than thicknesses of the read word line and the write word line in the first direction.

10. A bit cell comprising:
a read port comprising a read pass transistor and a read pull-down transistor; and
a write port comprising a first pass transistor, a second pass transistor, a first pull-down transistor, a second pull-down transistor, a first pull-up transistor, and a second pull-up transistor,
wherein the read pass transistor, the read pull-down transistor, the first pass transistor, and the first pull-down transistor share one active region.

11. The bit cell of claim 10, wherein the read pass transistor, the read pull-down transistor, the first pull-down transistor, and the first pass transistor comprise N-type transistors.

12. The bit cell of claim 10, further comprising a first wiring layer disposed on the active region and including a plurality of metal lines, wherein the first wiring layer extends in a direction parallel to the active region.

13. The bit cell of claim 10, further comprising:
a read word line connected to the read port and a write word line connected to the write port, which are disposed on the active region; and
a read bit line pad connected to the read port and a write bit line pad connected to the write port, which are disposed on the active region,
wherein lengths of the read bit line pad and the write bit line pad are less than lengths of the read word line and the write word line.

14. The bit cell of claim 12, further comprising a second wiring layer disposed on the first wiring layer and including a plurality of metal lines, wherein the second wiring layer extends in a direction perpendicular to the active region.

15. The bit cell of claim 14, wherein the second wiring layer further comprises a read bit line connected to the read port and a write bit line connected to the write port.

16. An integrated circuit device comprising:
a bit cell including a read port and a write port, comprising:
a plurality of active regions comprising a first active region, a second active region, a third active region, and a fourth active region, which are spaced apart from each other in parallel in a first direction and extend in a second direction perpendicular to the first direction; and
a plurality of gates comprising a first gate, a second gate, a third gate, and a fourth gate, which are spaced apart from each other in parallel in the second direction, extend in the first direction, and are arranged in at least one of the plurality of active regions to each form a transistor,
wherein the read port comprises a read pass transistor and a read pull-down transistor,
the write port comprises a first pass transistor, a second pass transistor, a first pull-down transistor, a second pull-down transistor, a first pull-up transistor, and a second pull-up transistor, and
the read pass transistor, the read pull-down transistor, the first pass transistor, and the first pull-down transistor share one active region.

17. The integrated circuit device of claim 16, wherein the read pass transistor, the read pull-down transistor, the first pull-down transistor, and the first pass transistor comprise N-type transistors.

18. The integrated circuit device of claim 16, wherein the first pull-up transistor and the second pull-up transistor comprise P-type transistors, and
the second pull-down transistor and the second pass transistor comprise N-type transistors.

19. The integrated circuit device of claim 16, further comprising a first wiring layer disposed on the plurality of gates and comprising a plurality of word lines electrically connected to each of the read port and the write port, wherein the first wiring layer extends in a direction parallel to the active region.

20. The integrated circuit device of claim 19, further comprising a second wiring layer disposed on the first wiring layer and comprising a plurality of bit lines electrically connected to each of the read port and the write port,
wherein the second wiring layer extends in a direction perpendicular to the active region.
